(19) United States
(12) Patent Application Publication
(10) Pub. No.: US 2018/0342342 A1
(43) Pub. Date: Nov. 29, 2018

(54) COIL BUILT-IN SUBSTRATE AND METHOD FOR MANUFACTURING THE SAME

(71) Applicant: IBIDEN CO., LTD., Ogaki (JP)

(72) Inventor: Hirotaka TANIGUCHI, Ogaki (JP)

(73) Assignee: IBIDEN CO., LTD., Ogaki (JP)

(21) Appl. No.: 15/988,034

(22) Filed: May 24, 2018

(30) Foreign Application Priority Data
May 24, 2017 (JP) 2017-102816

(51) Int. Cl. H01F 17/00; H05K 1/16; H01F 5/04; H01F 41/04

(52) U.S. Cl. CPC H01F 17/0033; H05K 1/165; H01F 41/041; H01F 5/04; H01F 17/0013

(57) ABSTRACT

A coil built-in substrate includes insulating layers, coil forming layers having spiral coil patterns such that each of the insulating layers is interposed between adjacent coil forming layers, connection conductors penetrating the insulating layers such that each of the connection conductors is connecting one spiral coil pattern of one coil forming layer to another spiral coil pattern of another coil forming layer, and a tubular core structure including a magnetic material and penetrates through the insulating layers such that the tubular core structure is penetrating center portions of the coil patterns in the coil forming layers.

### CROSS-REFERENCE TO RELATED APPLICATIONS

The present application is based upon and claims the benefit of priority to Japanese Patent Application No. 2017-102816, filed May 24, 2017, the entire contents of which are incorporated herein by reference.

### BACKGROUND OF THE INVENTION

### Field of the Invention

The present invention relates to a coil built-in substrate formed by laminating multiple conductor layers via interlayer insulating layers, the conductor layers each having a coil pattern.

### Description of Background Art

Japanese Patent Laid-Open Publication No. 2005-347286 describes a coil built-in substrate having a cylindrical iron core as a core penetrating coil patterns formed in multiple conductor layers. The entire contents of this publication are incorporated herein by reference.

### SUMMARY OF THE INVENTION

According to one aspect of the present invention, a coil built-in substrate includes insulating layers, coil forming layers having spiral coil patterns such that each of the insulating layers is interposed between adjacent coil forming layers, connection conductors penetrating the insulating layers such that each of the connection conductors is connecting one spiral coil pattern of one coil forming layer to another spiral coil pattern of another coil forming layer, and a tubular core structure including a magnetic material and penetrates through the insulating layers such that the tubular core structure is penetrating center portions of the coil patterns in the coil forming layers.

According to another aspect of the present invention, a method of manufacturing a coil built-in substrate includes forming a structure including insulating layers, conductor layers having spiral coil patterns such that each of the insulating layers is interposed between adjacent conductor layers, connection conductors penetrating the insulating layers such that each of the connection conductors is connecting one spiral coil pattern of one conductor layer to another spiral coil pattern of another conductor layer, forming a penetrating hole through the structure such that the penetrating hole penetrates center portions of the coil patterns in the conductor layers, coating a magnetic material on an inner surface of the penetrating hole such that a tubular core structure including the magnetic material is formed to penetrate through the insulating layers and the center portions of the coil patterns in the conductor layers.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional side view of a coil built-in substrate according to an embodiment of the present invention;

FIG. 2A is a cross-sectional plan view of a first conductor layer in an A-A cutting plane of FIG. 1;

FIG. 2B is a cross-sectional plan view of a second conductor layer in a B-B cutting plane of FIG. 1;

FIG. 3A-3D are cross-sectional side views illustrating manufacturing processes of the coil built-in substrate;

FIG. 4A-4D are cross-sectional side views illustrating manufacturing processes of the coil built-in substrate;

FIG. 5A-5C are cross-sectional side views illustrating manufacturing processes of the coil built-in substrate;

FIG. 6A and 6B are cross-sectional side views illustrating manufacturing processes of the coil built-in substrate; and

FIG. 7 is a cross-sectional side view illustrating a coil built-in substrate according to another embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### First Embodiment

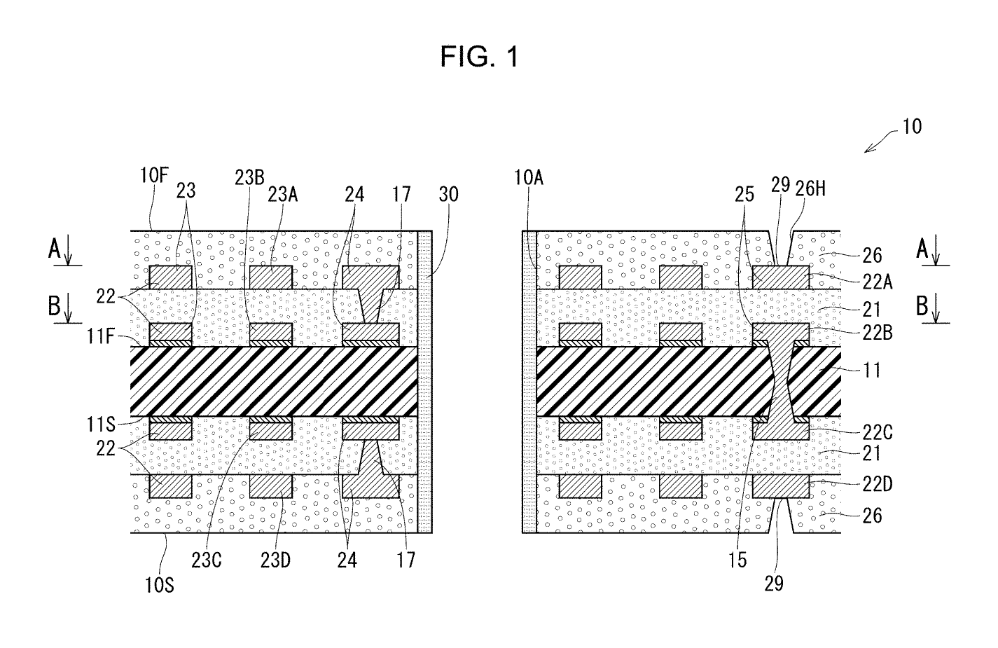

As illustrated in FIG. 1, a coil built-in substrate 10 of the present embodiment is formed to have a structure in which, on both front and back sides of an insulating base material 11, conductor layers 22 and interlayer insulating layers 21 are alternately laminated and solder resist layers (26, 26) are further laminated. The numbers of the conductor layers 22 and the interlayer insulating layers 21 are the same on both sides of the insulating base material 11. In the following, a surface at one end in a plate thickness direction of the coil built-in substrate 10 is referred to as an F surface (10F) and a surface at the other end is referred to as an S surface (10S).

The insulating base material 11 has an F surface (11F), which is a surface on the F surface (10F) side of the coil built-in substrate 10, and an S surface (11S), which is surface on a back side. The insulating base material 11 is a prepreg obtained by impregnating a woven fabric of reinforcing fibers (for example, a glass cloth) with a resin. The insulating base material 11 has a thickness of, for example, about 50-150 μm.

The interlayer insulating layers 21 and the solder resist layers 26 are each a resin layer that does not contain reinforcing fibers. The interlayer insulating layers 21 each have a thickness of, for example, about 15-30 μm. A thickness of each of the solder resist layers 26 is larger than the thickness of each of the interlayer insulating layers 21, and is, for example, about 18-35 μm. As will be described in detail later, the conductor layers 22 are each mainly formed of copper plating. A thickness of each of the conductor layers 22 is smaller than the thickness of each of the interlayer insulating layers 21 and is, for example, about 10-25 μm. When the multiple conductor layers 22 are distinguished from each other, the multiple conductor layers 22 are respectively referred to as a first conductor layer (22A), a second conductor layer (22B), a third conductor layer (22C), and a fourth conductor layer (22D) in an order from the outermost conductor layer 22 on the F surface (10F) side to the outermost conductor layer 22 on the S surface (105) side.

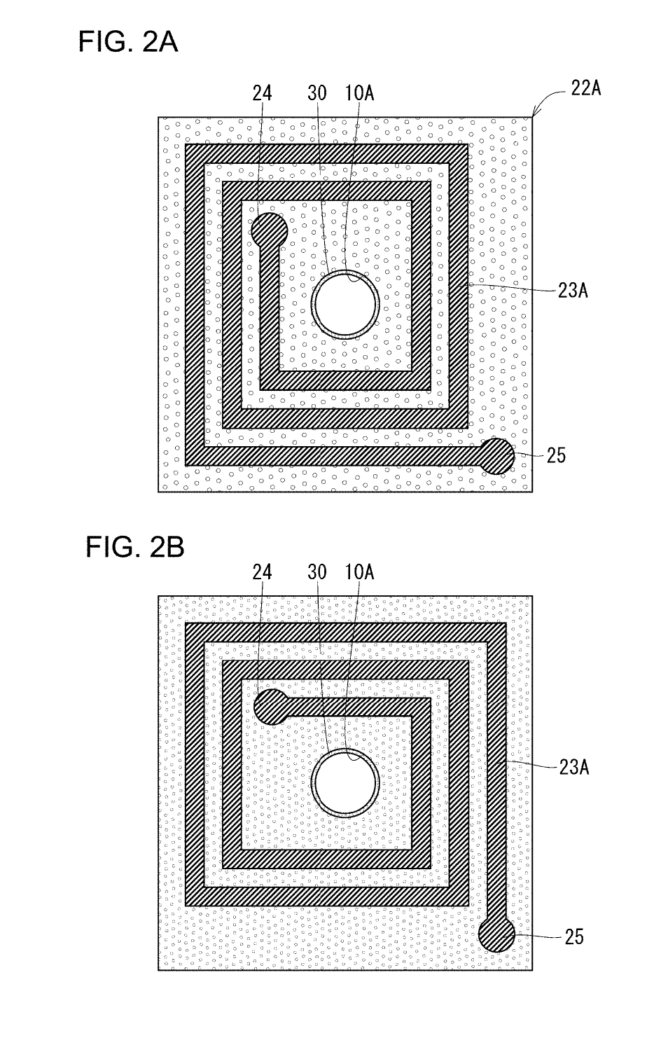

The first-fourth conductor layers (22A-22D) each have a coil pattern 23 (see FIG. 2A and 2B), and these coil patterns 23 are arranged in the plate thickness direction of the coil built-in substrate 10. Further, adjacent coil patterns (23, 23) are connected in series by via conductors 17 each penetrating an interlayer insulating layer 21 or by a connection conductor 15 penetrating the insulating base material 11, a pair of pads (29, 29) which respectively form both terminals of the series circuit are respectively provided on the F surface (10F) and the S surface (10S) of the coil built-in substrate 10. In the following, when the coil patterns 23 that are respectively formed in the first-fourth conductor layers (22A-22D) are distinguished from each other, the coil patterns 23 are respectively referred as a first coil pattern (23A), a second coil pattern (23B), a third coil pattern (23C), and a fourth coil pattern (23D) as appropriate. The via conductors 17 and the connection conductor 15 each corresponds to a “connection conductor” according to an embodiment of the present invention.

FIG. 2A illustrates a plan view of the coil built-in substrate 10 and a plan view of the first conductor layer (22A) viewed from the F surface (10F) side. As illustrated in

FIG. 2A, a planar shape of the coil built-in substrate 10 is a quadrangular shape. In the first conductor layer (22A), the first coil pattern (23A) is formed having a spiral shape wound three times counterclockwise from a center.

Further, an inner end of the first coil pattern (23A) is connected to an inner land part 24. Further, an outer end of the first coil pattern (23A) forms an outer land part 25 having substantially the same shape as the inner land part 24.

FIG. 2B illustrates a planar shape of the second conductor layer (22B) viewed from the F surface (10F) side. In the second conductor layer (22B), the second coil pattern (23B) is formed having a spiral shape wound three times clockwise from a center. The second conductor layer (22B) has the same structure as the first conductor layer (22A) except that the spiral of the second coil pattern (23B) is left handed.

In the third conductor layer (22C), the third coil pattern (23C) is formed having the same structure as the first coil pattern (23A). In the fourth conductor layer (22D), the fourth coil pattern (23D) is formed having the same structure as the second coil pattern (23B).

Between the first and second conductor layers (22A, 22B) and between the third and fourth conductor layers (22C, 22D), the inner land parts (24, 24) are connected to each other by the via conductor 17 penetrating the interlayer insulating layer 21. Further, between the second and the third conductor layers (22B, 22C), the outer land parts (25, 25) are connected to each other by the connection conductor 15 penetrating the insulating base material 11. That is, the multiple coil patterns 23 are connected to each other by connecting, from the F surface (10F) side, the inner ends, the outer ends and the inner ends in this order, and a series circuit of the multiple coil patterns 23 is formed. As a result, when a current flows through the series circuit of the multiple coil patterns 23, magnetic fluxes generated in the coil patterns 23 are oriented in the same direction.

However, as illustrated in FIG. 1, in the coil built-in substrate 10 of the present embodiment, a tubular core 30 penetrating center portions of the multiple coil patterns 23 is provided. An inner side of the tubular core 30 is hollowed. Specifically, the tubular core 30 has an outer diameter of substantially 1500-3500 μm. The tubular core 30 has an inner diameter of substantially 1400-3470 μm. The tubular core 30 has a thickness of substantially 15-50 μm.

The tubular core 30 is formed by covering an inner side surface of a through hole (10A) penetrating the coil built-in substrate 10 with a magnetic material. The magnetic material contains a resin and magnetic particles. Examples of the resin of the magnetic material include an epoxy resin, a phenol resin, a polybenzoxazole resin, a polyphenylene resin, a polybenzocyclobutene resin, a polyarylene ether resin, a polysiloxane resin, a polyurethane resin, a polyester resin, a polyester urethane resin, a fluorine resin, a polyolefin resin, a polycycloolefin resin, a cyanate resin, a polyphenylene ether resin, a polystyrene resin, and the like, or a mixture of these resins, and the like. The magnetic particles of the magnetic material are arbitrary as long as the magnetic particles are formed of a soft magnetic material. Examples of soft magnetic materials include iron, soft magnetic iron alloys, nickel, soft magnetic nickel alloys, cobalt, soft magnetic cobalt alloys, soft magnetic iron (Fe)—silicon (Si) based alloys, soft magnetic iron (Fe)—nitrogen (N) based alloys, soft magnetic iron (Fe)—carbon (C) based alloys, soft magnetic iron (Fe)—boron (B) based alloys, soft magnetic iron (Fe)—phosphorus (P) based alloys, soft magnetic iron (Fe)—aluminum (Al) based alloys, soft magnetic iron (Fe)—aluminum (Al)—silicon (Si) based alloys, and the like.

The coil built-in substrate 10 of the present embodiment is manufactured as follows.

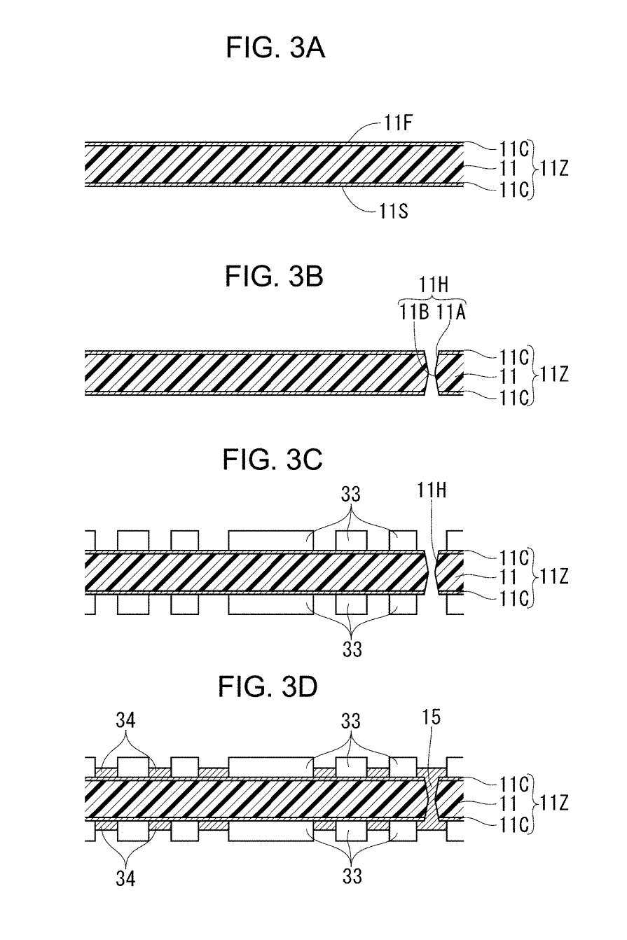

(1) As illustrated in FIG. 3A, a copper-clad laminated plate (11Z) is prepared in which a copper foil (11C) is laminated on both front and back sides of an insulating base material 11.

(2) As illustrated in FIG. 3B, a through hole (11H) for forming the connection conductor 15 (see FIG. 1) is formed in the copper-clad laminated plate (11Z). Specifically, a tapered hole (11A) and a tapered hole (11B) are respectively formed by irradiating, for example, CO2 laser from both sides of the copper-clad laminated plate (11Z), and the through hole (11H) for the connection conductor 15 is formed from the tapered holes (11A, 11B).

(3) An electroless plating treatment is performed. An electroless plating film (not illustrated in the drawings) is formed on the copper foil (11C) and on an inner surface of the through hole (11H). Next, as illustrated in FIG. 3C, a plating resist 33 of a predetermined pattern is formed on the electroless plating film on the copper foil (11C).

(4) As illustrated in FIG. 3D, an electrolytic plating treatment is performed. The through hole (11H) is filled with electrolytic plating and the connection conductor 15 is formed; and electrolytic plating films (34, 34) are formed on portions of the electroless plating film (not illustrated in the drawings) formed on the copper-clad laminated plate (11Z) the portions being exposed from the plating resist 33.

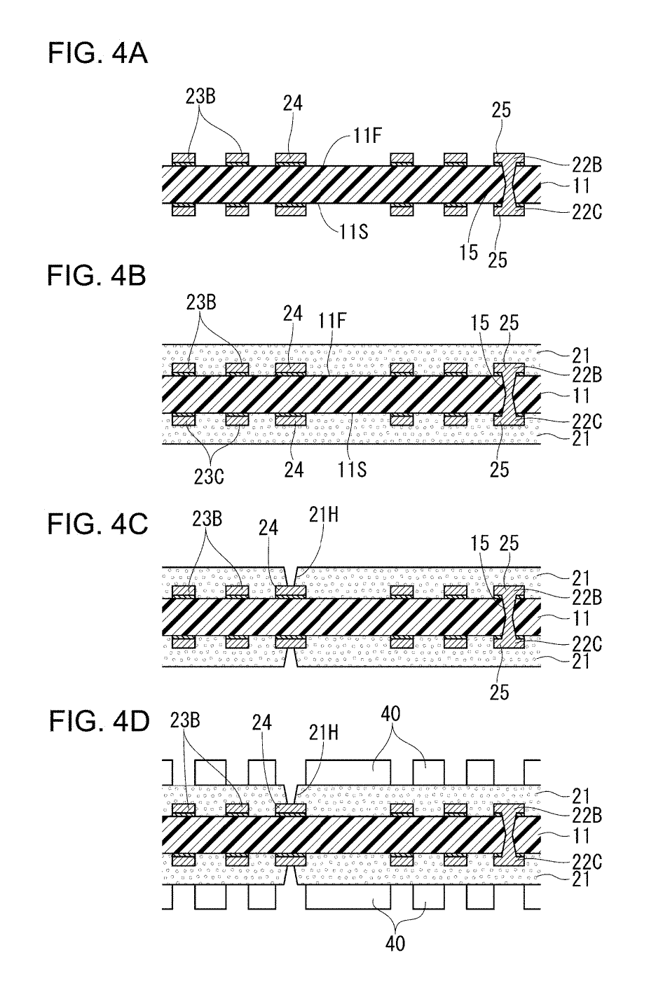

(5) The plating resist 33 is peeled off, and the electroless plating film (not illustrated in the drawings) and the copper foil (11C), which are below the plating resist 33, are removed. As illustrated in FIG. 4A, by the remaining electrolytic plating film 34, electroless plating film and copper foil (11C), the above-described second conductor layer (22B) is formed on the F surface (11F) of the insulating base material 11, and the above-described third conductor layer (22C) is formed on the S surface (11S) of the insulating base material 11. Further, the second and the third conductor layers (22B, 22C) are connected to each other by the connection conductor 15.

(6) As illustrated in FIG. 4B, the interlayer insulating layers (21, 21) are respectively laminated in the second conductor layer (22B) and on the third conductor layer (22C).

(7) As illustrated in FIG. 4C, by irradiating CO2 laser to the interlayer insulating layers (21, 21), tapered via holes (21H) penetrating the interlayer insulating layers 21 are formed.

(8) An electroless plating treatment is performed. An electroless plating film (not illustrated in the drawings) is formed on the interlayer insulating layers (21, 21) and on inner surfaces of the via holes (21H). Next, as illustrated in FIG. 4D, a plating resist 40 of a predetermined pattern is formed on the electroless plating film on the interlayer insulating layers (21, 21).

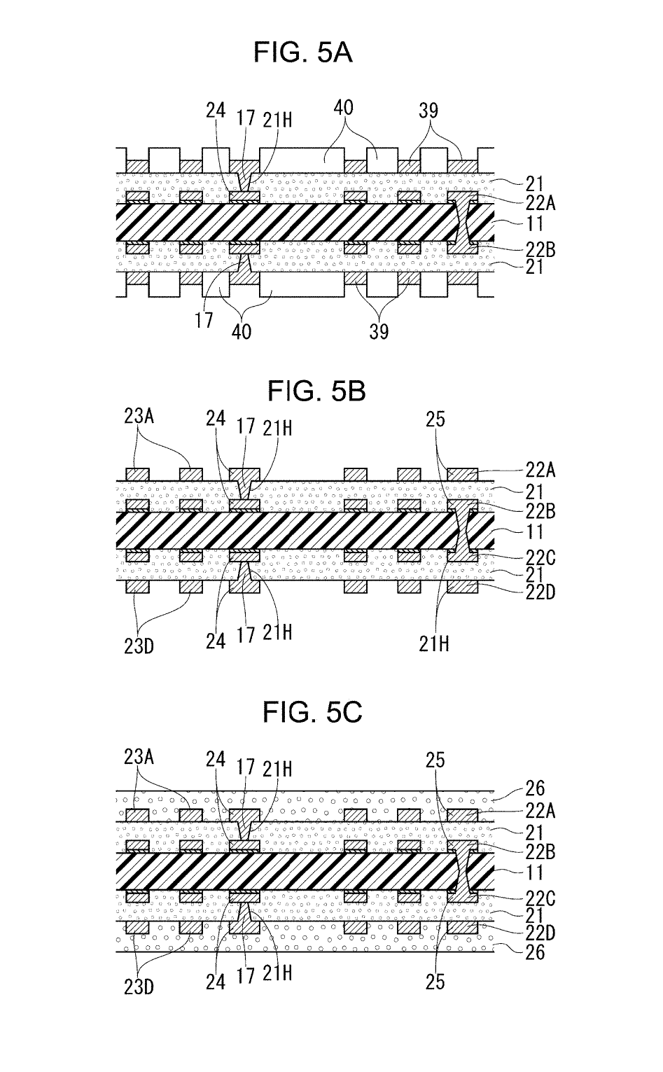

(9) An electrolytic plating treatment is performed. As illustrated in FIG. 5A, the via holes (21H) are filled with electrolytic plating and the via conductors 17 are formed; and electrolytic plating films (39, 39) are formed on portions of the electroless plating film (not illustrated in the drawings) on the interlayer insulating layers (21, 21), the portions being exposed from the plating resist 40.

(10) Next, as illustrated in FIG. 5B, the plating resist 40 is peeled off, and the electroless plating film (not illustrated in the drawings) below the plating resist 40 is removed. By the remaining electrolytic plating film 39 and electroless plating film, the first conductor layer (22A) is formed on the F surface (11F) side, and the fourth conductor layer (22D) is formed on the S surface (11S) side. Then, the first and second conductor layers (22A, 22B) are connected to each other by the via conductor 17, and the third and fourth conductor layers (22C, 22D) are connected to each other by the via conductor 17.

(11) As illustrated in FIG. 5C, the solder resist layers (26, 26) are respectively laminated on the first and fourth conductor layers (22A, 22D).

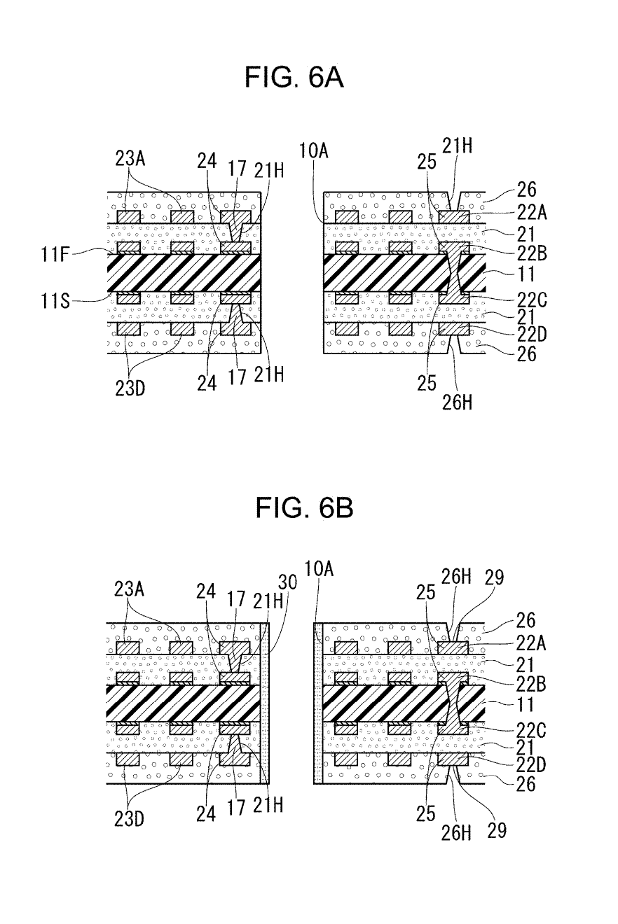

(12) Then, as illustrated in FIG. 6A, by router process, the through hole (10A) penetrating the solder resist layers (26, 26), the conductor layers (22, 22), the interlayer insulating layers (21, 21) and the insulating base material 11 is formed. The through hole (10A) is formed at a substantially center portion of each of the coil patterns (23, 23). Further, by laser processing, a tapered opening (26A) is formed at a predetermined place of each of the F surface (11F) side and S surface (11S) side solder resist layers (26, 26), and a portion of the outer land part 25 of the first conductor layer (22A) and a portion of the outer land part 25 of the fourth conductor layer (22D) are exposed from the solder resist layers 26, and the pair of the pads (29, 29) are formed.

(13) As illustrated in FIG. 6B, the tubular core 30 covering an inner peripheral surface of the through hole (10A) is formed. The tubular core 30 is formed using a method in which a resin containing magnetic particles is applied or is sprayed using a spray or the like. As a result, the coil built-in substrate 10 illustrated in FIG. 1 is completed.

The coil built-in substrate 10 of the present embodiment is used, for example, as a coil element. Specifically, for example, the pair of the pads (29, 29) of the coil built-in substrate 10 are arranged opposing a pair of pads of a circuit board (not illustrated in the drawings) and are connected by solder balls provided on any ones of the pads. In this way, the coil built-in substrate 10 can be used as a coil element of a circuit on a circuit board.

Further, the coil built-in substrate 10 can also be used as a component of a sensor. In the coil built-in substrate 10 of the present embodiment, the tubular core 30 composed of a magnetic material penetrating substantially center portions of the coil patterns (23, 23) is formed. That is, the coil built-in substrate 10 of the present embodiment has a shape in which the inner side of the core is hollowed, and thus, can be reduced in weight as compared to a coil built-in substrate having a cylindrical iron core at the center portions of the coil patterns (23, 23). Further, by having the tubular core 30 at substantially center portions of the coil patterns (23, 23), the coil built-in substrate 10 of the present embodiment can improve transmission efficiency as compared to a coil built-in substrate having an air core. That is, the coil built-in substrate 10 of the present embodiment can improve transmission efficiency as compared to a coil built-in substrate having an air core and can be reduced in weight as compared to a coil built-in substrate having a cylindrical iron core.

### Second Embodiment

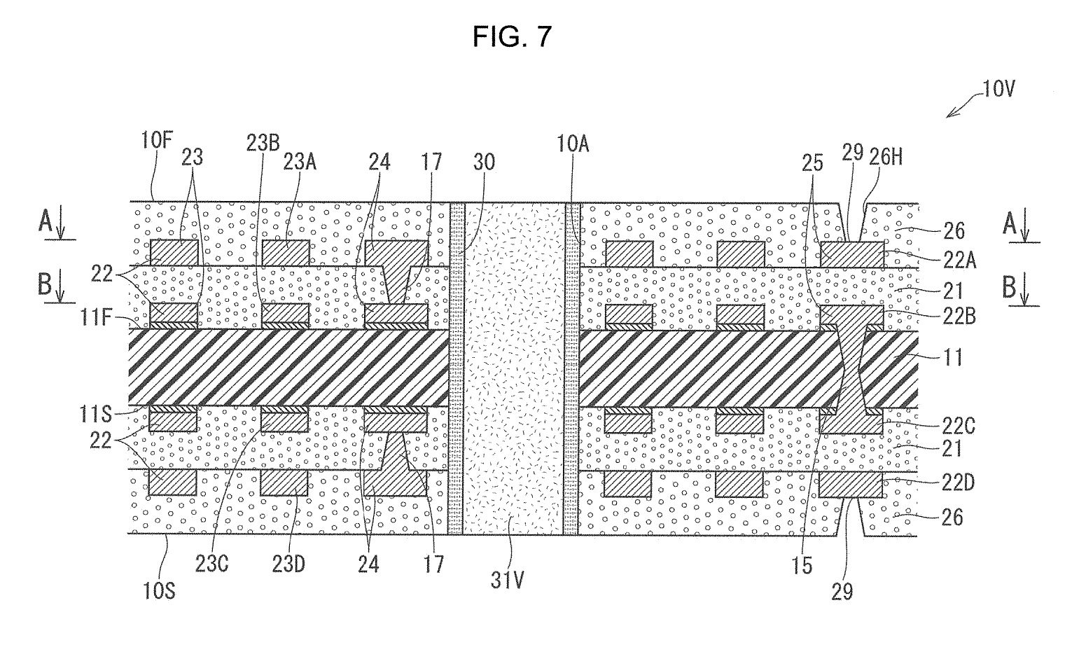

A second embodiment is described with reference to FIG. 7. In a coil built-in substrate (10V) of the present embodiment, the inside of the tubular core 30 of the coil built-in substrate 10 of the first embodiment is filled with a filler 31. As a result, strength of the coil built-in substrate (10V) can be increased. The filler 31 means, for example, an epoxy resin, a phenol resin, a fluorine resin, a triazine resin, a polyolefin resin, a polyphenylene ether resin, and the like, and may be a thermosetting resin, a thermoplastic resin or a composite thereof, and may contain an inorganic filler such as silica or alumina in a resin to adjust a thermal expansion coefficient or the like.

For the coil built-in substrate (10V) of the present embodiment, after the above-described processes (1)-(13) of the manufacturing method of the first embodiment are performed, the inner side of the tubular core 30 is filled with a filler (31V). Then, the filler (31V) is cured, and surfaces of the coil built-in substrate (10V) are flattened by polishing the filler (31V) protruding from the tubular core 30 such that surfaces of the filler (31V) are substantially flush with upper surfaces of the solder resist layers (26, 26). As a result, the coil built-in substrate (10V) illustrated in FIG. 7 is completed.

### Other Embodiments

(1) In the coil built-in substrate 10 of the above embodiment, the coil patterns 23 are provided at only one place in the planar shape. However, it is also possible that the coil patterns 23 are provided at multiple places in the planar shape.

(2) In the coil built-in substrate 10 of the above embodiment, the winding directions of the spirals of the adjacent coil patterns 23 are different from each other. However, it is also possible that the winding directions are the same.

(3) In the coil built-in substrate 10 of the above embodiment, the shape of each of the lands is circular. However, it is also possible that the shape of each of the lands is rectangular.

(4) In the coil built-in substrate 10 of the above embodiment, the coil patterns 23 each have a rectangular spiral shape. However, it is also possible that the coil patterns 23 each have a circular spiral shape.

(5) It is sufficient that the inside of each of the tubular cores (30, 30V) is hollowed. For example, the tubular cores (30, 30V) may each have a circular tubular shape or a rectangular tubular shape.

Weight reduction is desired in the coil built-in substrate of Japanese Patent Laid-Open Publication No. 2005-347286.

A coil built-in substrate according to an embodiment of the present invention allows weight reduction to be achieved as compared to a conventional coil built-in substrate.

A coil built-in substrate according to an embodiment of the present invention includes: multiple coil forming layers each having a spiral coil pattern; insulating layers interposed between the multiple coil forming layers; and connection conductors penetrating the insulating layers and connecting the coil patterns of the multiple coil forming layers. A tubular core composed of a magnetic material penetrates center portions of the multiple coil patterns.

Obviously, numerous modifications and variations of the present invention are possible in light of the above teachings. It is therefore to be understood that within the scope of the appended claims, the invention may be practiced otherwise than as specifically described herein.

1. A coil built-in substrate, comprising:
a plurality of insulating layers;
a plurality of coil forming layers having a plurality of spiral coil patterns respectively such that each of the insulating layers is interposed between adjacent coil forming layers;
a plurality of connection conductors penetrating the insulating layers such that each of the connection conductors is connecting one spiral coil pattern of one coil forming layer to another spiral coil pattern of another coil forming layer; and
a tubular core structure comprising a magnetic material and penetrates through the plurality of insulating layers such that the tubular core structure is penetrating center portions of the coil patterns in the coil forming layers.

2. A coil built-in substrate according to claim 1, wherein the tubular core structure has a hollowed inner side space.

3. A coil built-in substrate according to claim 1, wherein the tubular core structure has an inner side space and filler material filling the inner side space.

4. A coil built-in substrate according to claim 1, wherein the tubular core structure has a thickness in a range of 15 μm to 50 μm.

5. A coil built-in substrate according to claim 2, wherein the tubular core structure has a thickness in a range of 15 μm to 50 μm.

6. A coil built-in substrate according to claim 3, wherein the tubular core structure has a thickness in a range of 15 μm to 50 μm.

7. A coil built-in substrate according to claim 1, wherein the plurality of insulating layer includes an insulating base material layer such that the coil forming layers includes a plurality of first coil forming layers formed on a first side of the insulating base material layer and a plurality of second coil forming layers formed on a second side of the insulating base material layer on an opposite side with respect o the first side.

8. A coil built-in substrate according to claim 7, wherein the tubular core structure has a hollowed inner side space.

9. A coil built-in substrate according to claim 7, wherein the tubular core structure has an inner side space and filler material filling the inner side space.

10. A coil built-in substrate according to claim 7, wherein the tubular core structure has a thickness in a range of 15 μm to 50 μm.

11. A coil built-in substrate according to claim 8, wherein the tubular core structure has a thickness in a range of 15 μm to 50 μm.

12. A coil built-in substrate according to claim 9, wherein the tubular core structure has a thickness in a range of 15 μm to 50 μm.

13. A coil built-in substrate according to claim 1, wherein the plurality of insulating layers includes a solder resist layer formed on an outermost coil forming layer of the plurality of coil forming layers.

14. A coil built-in substrate according to claim 7, wherein the plurality of insulating layers includes a solder resist layer formed on an outermost coil forming layer of the plurality of coil forming layers.

15. A method of manufacturing a coil built-in substrate, comprising:
forming a structure comprising a plurality of insulating layers, a plurality of conductor layers having a plurality of spiral coil patterns respectively such that each of the insulating layers is interposed between adjacent conductor layers, a plurality of connection conductors penetrating the insulating layers such that each of the connection conductors is connecting one spiral coil pattern of one conductor layer to another spiral coil pattern of another conductor layer;
forming a penetrating hole through the structure such that the penetrating hole penetrates center portions of the coil patterns in the conductor layers;
coating a magnetic material on an inner surface of the penetrating hole such that a tubular core structure comprising the magnetic material is formed to penetrate through the plurality of insulating layers and the center portions of the coil patterns in the conductor layers.

16. A method of manufacturing a coil built-in substrate according to claim 15, wherein the plurality of insulating layers includes a solder resist layer formed on an outermost conductor layer of the plurality of conductor layers.

17. A method of manufacturing a coil built-in substrate according to claim 15, wherein the coating of the magnetic material comprises forming the tubular core structure having a hollowed inner side space.

18. A method of manufacturing a coil built-in substrate according to claim 15, wherein the coating of the magnetic material comprises forming the tubular core structure having an inner side space and filling the inner side space with filler material.

19. A method of manufacturing a coil built-in substrate according to claim 15, wherein the coating of the magnetic material comprises forming the tubular core structure having a thickness in a range of 15 μm to 50 μm.

20. A method of manufacturing a coil built-in substrate according to claim 16, wherein the coating of the magnetic material comprises forming the tubular core structure having a thickness in a range of 15 μm to 50 μm.
